(19) United States
(12) Patent Application Publication
(10) Pub. No.: US 2013/0328570 A1
(43) Pub. Date: Dec. 12, 2013

(54) TEST DEVICE FOR TESTING DISC PLAYER

(71) Applicants: Hong Fu Jin Precision Industry (ShenZhen) Co., LTD., (US); HON HAI PRECISION INDUSTRY CO., LTD., New Taipei (TW)

(72) Inventor: XIAO-QING ZHANG, Shenzhen (CN)

(73) Assignees: Hon Hai Precision Industry Co., Ltd., New Taipei (TW); HONG FU JIN PRECISION INDUSTRY (ShenZhen) CO., LTD., Shenzhen (CN)

(21) Appl. No.: 13/869,094

(22) Filed: Apr. 24, 2013

(30) Foreign Application Priority Data
Jun. 8, 2012 (CN) 2012101872450

(51) Int. Cl. G01R 31/02

(52) U.S. Cl. CPC G01R 31/021
USPC 324/543

(57) ABSTRACT

A test device is used for testing a disc player, the disc player includes a power terminal and an audio output terminal The power terminal outputs a supply voltage when the disc player reads a disc. The test device includes a detecting unit connected to the power terminal and the audio output terminal, the detecting unit being powered by the supply voltage to detect whether the audio output terminal outputs a digital audio signal and generate a first level signal when the detecting unit detects that the audio output terminal outputs the digital audio signal; and a processing unit responding to the first level signal by determining that the audio output terminal of the disc player successfully outputs the digital audio signal.

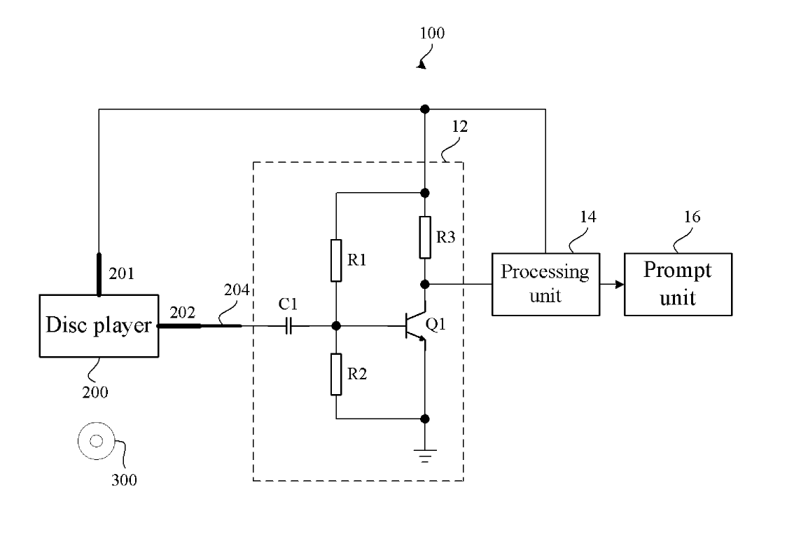

### BACKGROUND

1. Technical Field

The disclosed embodiments relate to a test device for testing a disc player.

2. Description of Related Art

Most disc players, such as digital versatile disc (DVD) players, include a coaxial output terminal for outputting digital audio signals. In the manufacturing process of a plurality of DVD players, there is a demand to test whether the coaxial output terminal of each DVD player successfully outputs digital audio signals. If it is determined that the coaxial output terminal fails to outputs digital audio signals, the quality of corresponding DVD player is bad.

A common test method is described as follows: firstly, connecting the coaxial output terminal of the DVD player to an audio reproducing device through the coaxial cable; secondly, loading a disc in the DVD player and controlling the DVD player to read the disc, thirdly, determining that the coaxial output terminal of the DVD player successfully outputs digital audio signals when the user hears sounds outputted by the audio reproducing device; and determining that the quality of the DVD player is bad when the user fails to hear sounds outputted by the audio reproducing device.

However, in the above test method, the user determines whether the coaxial output terminal successfully outputs the digital audio signals, therefore, it is not realized to automatically determine whether the coaxial output terminal successfully outputs the digital audio signals.

Therefore, there is room for improvement in the art.

### BRIEF DESCRIPTION OF THE DRAWINGS

Many aspects of the embodiments can be better understood with reference to the drawing. The components in the drawing are not necessarily drawn to scale, the emphasis instead being placed upon clearly illustrating the principles of the present embodiments. Moreover, in the drawing, like reference numerals designate corresponding parts throughout one view.

FIGURE is a schematic block diagram showing a test device in accordance with one embodiment.

### DETAILED DESCRIPTION

Referring to the FIGURE, a test device 100 in accordance with one embodiment is illustrated, the test device 100 is used for testing a disc player 200. In the embodiment, the disc player 200 is a digital versatile disc (DVD) player.

The disc player 200 includes a power terminal 201 and an audio output terminal 202. When the disc player 200 reads a disc 300, the power terminal 201 outputs a supply voltage, and the audio output terminal 202 outputs a digital audio signal. In the embodiment, the supply voltage is 3.3 volts.

The test device 100 includes a detecting unit 12, a processing unit 14, and a prompt unit 16.

The detecting unit 12 is connected to the power terminal 201 and the audio output terminal 202. When the detecting unit 12 receives the supply voltage from the power terminal 201, the detecting unit 12 is powered by the supply voltage to detect whether the audio output terminal 202 outputs the digital audio signal. The detecting unit 12 generates a first level signal when the detecting unit 12 detects that the audio output terminal 202 successfully outputs the digital audio signal. The detecting unit 12 further generates a second level signal when the detecting unit 12 fails to detect the digital audio signal. In the embodiment, the first level signal is a low level (digital low) signal, the second level signal is a high level (digital high) signal, and the voltage value of the first level signal is substantially zero volts.

The processing unit 14 responds to the first level signal by determining that the audio output terminal 202 successfully outputs the digital audio signal and controlling the prompt unit 16 to output an indication, for example a visual or audible indication, that the audio output terminal 202 of the disc player 200 successfully outputs the digital audio signal.

The processing unit 14 further responds to the second level signal by determining that the audio output terminal 202 fails to output the digital audio signal and controlling the prompt unit 16 to output the indication, for example the visual or audible indication, that the quality of the disc player 200 is bad.

In the embodiment, the audio output terminal 202 is a coaxial output terminal, the detecting unit 12 is connected to the audio output terminal 202 through the coaxial cable 204; the digital audio signal is a square wave signal having a upper voltage value and a lower voltage value, the processing unit 14 is connected to the power terminal 201 and preset a predetermined time period from a time point when the power terminal 201 outputs the supply voltage, during the predetermined time period, the upper voltage value of the digital audio signal is transmitted to the detecting unit 12 and controls the detecting unit 12 to output the first level signal, therefore the processing unit 14 receives the first level signal during the predetermined time period; the reasons are described hereinafter. In other embodiments, the audio output terminal 202 is an optical output terminal, the coaxial cable 204 is replaced by a fiber optic cable, and the detecting unit 12 is connected to the audio output terminal 202 through the fiber optic cable.

In detail, the detecting unit 12 includes a first resistor R1, a second resistor R2, a third resistor R3, and a transistor Q1. The first resistor R1 and the second resistor R2 are connected in series between the power terminal 201 and ground, a control electrode of the transistor Q1 is connected between the first resistor R1 and the second resistor R2, a first conducting electrode of the transistor Q1 is connected to the power terminal 201 through the third resistor R3, the first conducting electrode of the transistor Q1 is further connected to the processing unit 14, and a second conducting electrode of the transistor Q1 is grounded. A first end of the capacitor C1 is connected to the audio output terminal 202, and a second end of the capacitor C1 is connected to the control electrode of the transistor Q1.

In the embodiment, the transistor Q1 is a npn type bipolar junction transistor, the control electrode is a base of the transistor, the first conducting electrode is a collector of the transistor, the second conducting electrode is an emitter of the transistor.

The principle of the test device 100 is that when the disc player 200 reads the disc 300, the audio output terminal (coaxial output terminal) 202 outputs the digital audio signal, the digital audio signal is a square wave signal having a upper voltage value of +0.5 volts and a lower voltage value of −0.5 volts.

In this embodiment, the resistance of the first resistor R1 is 12KΩ, the resistance of the second resistor R2 is 2.2KΩ, and the supply voltage outputted by the power terminal 201 is 3.3 Volts. The voltage across the second resistor R2 is calculated by the formula: VR2=3.3*R2/(R1+R2)=3.3*2.2/14.2≈0.5 volts. In the embodiment, because the audio output terminal 202 is a coaxial output terminal, the processing unit 14 is connected to the power terminal 201 and preset the predetermined time period from the time point when the power terminal 201 outputs the supply voltage, the processing unit 14 receive the first level signal during the predetermined time period, the reasons are explained below.

When the disc player 200 reads the disc 300 and the audio output terminal 202 outputs the digital audio signal, because the digital audio signal is the square wave signal having the upper voltage value of +0.5 volts and the lower voltage value of −0.5 volts, during the predetermined time period from the time point when the power terminal 201 outputs the supply voltage, the voltage applied to the base of the transistor Q1 can be 1 volts, thus turning on the transistor Q1. Therefore, during the predetermined time period preset by the processing unit 14, the low level signal whose voltage value is 0 volts is transmitted to the processing unit 14, and causing the processing unit 14 to control the prompt unit 16 to output the indication that the audio output terminal 202 of the disc player 200 successfully outputs the digital audio signal.

When the disc player 200 reads the disc 300 and the audio output terminal 202 fails to output the digital audio signal, the voltage applied to the base of the transistor Q1 is 0.5 volts, thus turning off the transistor Q1, therefore, the high level signal whose voltage value is 3.3 volts is transmitted to the processing unit 14, and causing the processing unit 14 to control the prompt unit 16 to output the indication that the quality of the disc player 200 is bad.

The purpose of the detecting unit 12 is described below: the digital audio signal outputted by the audio output terminal 202 is the square wave signal having the upper voltage value of +0.5 volts and the lower voltage value of −0.5 volts, because the processing unit 14 can identify the level signal whose voltage value is either 0 volts or 3.3 volts, and cannot identify the level signal whose voltage value is +0.5 volts or −0.5 volts. If the digital audio signal is directly transmitted to the processing unit 14, the processing unit 14 cannot identify the digital audio signal, therefore the test of the disc player 200 cannot be performed. Because the detecting unit 12 receives the digital audio signal and can identify the digital audio signal to output the level signal whose voltage value is 0 volts, and the level signal can be identified by the processing unit 14, so that the processing unit 14 controls the prompt unit 16 to output the indication that the audio output terminal 202 of the disc player 200 successfully outputs the digital audio signal, this is of great benefit for users.

Alternative embodiments will become apparent to those skilled in the art without departing from the spirit and scope of what is claimed. Accordingly, the present disclosure should not be deemed to be limited to the above detailed description, but rather only by the claims that follow and the equivalents thereof.

What is claimed is:

1. A test device for testing a disc player, the disc player comprising a power terminal and an audio output terminal, the power terminal outputting a supply voltage when the disc player reads a disc, the test device comprising:
a detecting unit connected to the power terminal and the audio output terminal, the detecting unit being powered by the supply voltage to detect whether the audio output terminal outputs a digital audio signal and generate a first level signal when the detecting unit detects that the audio output terminal outputs the digital audio signal; and
a processing unit responding to the first level signal by determining that the audio output terminal successfully outputs the digital audio signal.

2. The test device of claim 1, wherein the detecting unit further generates a second level signal when the detecting unit fails to detect the digital audio signal, the processing unit responds to the second level signal by determining that the audio output terminal fails to output the digital audio signal.

3. The test device of claim 2, further comprising a prompt unit, wherein the processing unit further responds to the first level signal by controlling the prompt unit to output an indication that the audio output terminal of the disc player successfully outputs the digital audio signal, the processing unit further responds to the second level signal by controlling the prompt unit to output the indication that the quality of the disc player is bad.

4. The test device of claim 2, wherein the audio output terminal is a coaxial output terminal, the detecting unit is connected to the audio output terminal through a coaxial cable.

5. The test device of claim 2, wherein the audio output terminal is an optical output terminal, the detecting unit is connected to the audio output terminal through a fiber optic cable.

6. The test device of claim 2, wherein the first level signal is a low level signal, and the second level signal is a high level signal.

7. The test device of claim 6, wherein the voltage value of the first level signal is zero volts.

8. The test device of claim 2, wherein the detecting unit comprises a first resistor, a second resistor, a third resistor, and a transistor; the first resistor and the second resistor are connected in series between the power terminal and ground, a control electrode of the transistor is connected between the first resistor and the second resistor, a first conducting electrode of the transistor is connected to the power terminal through the third resistor, the first conducting electrode of the transistor is further connected to the processing unit, and a second conducting electrode of the transistor is grounded.

9. The test device of claim 8, wherein the transistor is a npn type bipolar junction transistor, the control electrode is a base of the transistor, the first conducting electrode is a collector of the transistor, the second conducting electrode is an emitter of the transistor.

10. The test device of claim 8, wherein the detecting unit further comprises a capacitor, a first end of the capacitor is connected to the audio output terminal, and a second end of the capacitor is connected to the control electrode of the transistor.

11. The test device of claim 8, wherein the audio output terminal is a coaxial output terminal, the detecting unit is connected to the audio output terminal through a coaxial cable, the digital audio signal is a square wave signal having a upper voltage value and a lower voltage value, the processing unit is connected to the power terminal and to preset a predetermined time period from a time point when the power terminal outputs the supply voltage, during the predetermined time period, the upper voltage value of the digital audio signal is transmitted to the base of the transistor and turn on the transistor, therefore the processing unit receives the first level signal during the predetermined time period.

12. The test device of claim 2, wherein the audio output terminal is a coaxial output terminal, the detecting unit is connected to the audio output terminal through a coaxial cable, the digital audio signal is a square wave signal having a upper voltage value and a lower voltage value, the processing unit is connected to the power terminal and to preset a predetermined time period from a time point when the power terminal outputs the supply voltage, during the predetermined time period, the upper voltage value of the digital audio signal is transmitted to the detecting unit and controls the detecting unit to output the first level signal, therefore the processing unit receives the first level signal during the predetermined time period.
